(19) United States
(12) Patent Application Publication
(10) Pub. No.: US 2025/0285679 A1
(43) Pub. Date: Sep. 11, 2025

(54) MEMORY DEVICE AND OPERATION METHOD THEREOF, MEMORY SYSTEM

(71) Applicant: Yangtze Memory Technologies Co., Ltd., Wuhan (CN)

(72) Inventors: Xiangnan ZHAO, Wuhan (CN); Chenhui LI, Wuhan (CN); Kaikai YOU, Wuhan (CN)

(21) Appl. No.: 18/886,951

(22) Filed: Sep. 16, 2024

(30) Foreign Application Priority Data
Mar. 8, 2024 (CN) 202410272466.0

(51) Int. Cl. G11C 16/08; G11C 16/04

(52) U.S. Cl. CPC G11C 16/08; G11C 16/0483

(57) ABSTRACT

The present disclosure provides a memory device and an operation method thereof, a memory system, and a computer readable storage medium. The memory device includes: a memory array and a peripheral circuit coupled with the memory array. The memory array includes a plurality of memory cell strings and a conductive line coupled with one end of a memory cell string. The peripheral circuit is configured to: apply a first precharge voltage to the conductive line in a precharge stage of a first program cycle; and apply a second precharge voltage to the conductive line in a precharge stage of a second program cycle after the first program cycle, wherein the second precharge voltage is greater than the first precharge voltage.

### CROSS-REFERENCE TO RELATED APPLICATION

The present disclosure claims the benefit of priority to China Application No. 202410272466.0, filed on Mar. 8, 2024, the content of which is incorporated herein by reference in its entirety.

### TECHNICAL FIELD

The present disclosure relates to the technical field of semiconductors, and particularly to a memory device and an operation method thereof, a memory system, and a computer readable storage medium.

### BACKGROUND

As data memory technologies develop by leaps and bounds, increasingly more data memory systems are present in electronic apparatuses used by people, e.g., Solid State Drives (SSDs), etc. The SSDs are widely applied in military, on-vehicle, industry, medical and aviation fields etc. due to characteristics such as fast read and write speeds, vibration resistance, low power consumption, noiselessness, low heat, and light weight, etc.

### SUMMARY

In view of above, examples of the present disclosure provide a memory device and an operation method thereof, a memory system, and a computer readable storage medium.

In a first aspect, examples of the present disclosure provide a memory device, comprising: a memory array and a peripheral circuit coupled with the memory array, wherein the memory array comprises a plurality of memory cell strings and a conductive line coupled with one end of a memory cell string; the peripheral circuit is configured to: apply a first precharge voltage to the conductive line in a precharge stage of a first program cycle; and apply a second precharge voltage to the conductive line in a precharge stage of a second program cycle following the first program cycle, wherein the second precharge voltage is greater than the first precharge voltage.

In an example implementation, the peripheral circuit is further configured to: apply a third precharge voltage to the conductive line in a precharge stage of a third program cycle following the second program cycle, wherein the third precharge voltage is greater than the second precharge voltage.

In an example implementation, the first precharge voltage, the second precharge voltage, and the third precharge voltage present a stepwise increasing trend or a linear increasing trend.

In an example implementation, the peripheral circuit is further configured to: apply a first voltage to a word line coupled with a target memory cell in the precharge stage of the first program cycle; and apply a second voltage to the word line coupled with the target memory cell in the precharge stage of the second program cycle, wherein the second voltage is greater than the first voltage.

In an example implementation, the memory array further comprises a first word line group adjacent to the word line coupled with the target memory cell; the word line coupled with the target memory cell is located between the conductive line and the first word line group, the first word line group comprises at least one first word line and at least one second word line, the first word line is close to the word line coupled with the target memory cell, and the second word line is away from the word line coupled with the target memory cell; the peripheral circuit is further configured to at least one of: apply a third voltage to the first word line in the precharge stage of the first program cycle, wherein the third voltage is less than or equal to the first voltage; or apply a fourth voltage to the first word line in the precharge stage of the second program cycle, wherein the fourth voltage is less than or equal to the second voltage, and the fourth voltage is greater than the third voltage.

In an example implementation, the peripheral circuit is further configured to at least one of: apply a fifth voltage to the second word line in the precharge stage of the first program cycle, wherein the fifth voltage is less than the third voltage; or apply a sixth voltage to the second word line in the precharge stage of the second program cycle, wherein the sixth voltage is less than the fourth voltage, and the sixth voltage is greater than the fifth voltage.

In an example implementation, the first program cycle comprises at least one first pulse stage, and the second program cycle comprises at least one second pulse stage; the peripheral circuit is configured to: apply a corresponding first precharge voltage to the conductive line in each of the first pulse stages; and apply a corresponding second precharge voltage to the conductive line in each of the second pulse stages; in the first program cycle, a first precharge voltage applied in a first pulse stage arranged in the front in sequence is less than or equal to a first precharge voltage applied in a first pulse stage arranged behind in sequence; in the second program cycle, a second precharge voltage applied in a second pulse stage arranged in the front in sequence is less than or equal to a second precharge voltage applied in a second pulse stage arranged behind in sequence.

In an example implementation, at least one of: a plurality of first precharge voltages applied correspondingly in the plurality of first pulse stages arranged in sequence present a stepwise increasing trend or a linear increasing trend; or a plurality of second precharge voltages applied correspondingly in the plurality of second pulse stages arranged in sequence present a stepwise increasing trend or a linear increasing trend.

In an example implementation, the peripheral circuit is configured to: apply a corresponding first voltage to the word line coupled with the target memory cell in each of the first pulse stages; and apply a corresponding second voltage to the word line coupled with the target memory cell in each of the second pulse stages, wherein in the first program cycle, a first voltage applied in a first pulse stage arranged in the front in sequence is less than or equal to a first voltage applied in a first pulse stage arranged behind in sequence; in the second program cycle, a second voltage applied in a second pulse stage arranged in the front in sequence is less than or equal to a second voltage applied in a second pulse stage arranged behind in sequence.

In an example implementation, at least one of: a plurality of first voltages applied correspondingly in the plurality of first pulse stages arranged in sequence present a stepwise increasing trend or a linear increasing trend; or a plurality of second voltages applied correspondingly in the plurality of second pulse stages arranged in sequence present a stepwise increasing trend or a linear increasing trend.

In an example implementation, the conductive line comprises a bit line or a common source line.

In an example implementation, the memory array further comprises a second word line group, the second word line group comprises at least one third word line, and the second word line group is adjacent to the word line coupled with the target memory cell and located between the word line coupled with the target memory cell and the conductive line; the peripheral circuit is further configured to: apply a seventh voltage to the third word line in the precharge stage of the first program cycle; and apply an eighth voltage to the third word line in the precharge stage of the second program cycle, wherein the seventh voltage is less than the eighth voltage.

In an example implementation, the memory array further comprises a third word line group, the third word line group comprises at least one fourth word line, and the third word line group is located between the second word line group and the conductive line; the peripheral circuit is further configured to: connect the fourth word line to a ground voltage in the precharge stage of the first program cycle and the precharge stage of the second program cycle.

In an example implementation, the peripheral circuit is further configured to: apply a first program voltage to the word line coupled with the target memory cell in a program voltage application stage of the first program cycle; and apply a second program voltage to the word line coupled with the target memory cell in a program voltage application stage of the second program cycle, wherein the second program voltage is greater than the first program voltage.

In an example implementation, the conductive line comprises the common source line, and the memory array further comprises a bit line coupled with the other end of the memory cell string; the peripheral circuit is further configured to: apply a program inhibit voltage to bit lines other than a bit line coupled with the target memory cell in the precharge stage and the program voltage application stage of the first program cycle and in the precharge stage and the program voltage application stage of the second program cycle.

In a second aspect, examples of the present disclosure provide a memory system, comprising a memory controller and a memory device of any one of above examples, wherein the memory controller is coupled with the memory device and configured to control the memory device.

In a third aspect, examples of the present disclosure provide an operation method of a memory device, wherein the memory device comprises a plurality of memory cell strings and a conductive line coupled with one end of a memory cell string; the operation method comprises: applying a first precharge voltage to the conductive line in a precharge stage of a first program cycle; and applying a second precharge voltage to the conductive line in a precharge stage of a second program cycle following the first program cycle, wherein the second precharge voltage is greater than the first precharge voltage.

In an example implementation, the operation method further comprises: applying a third precharge voltage to the conductive line in a precharge stage of a third program cycle following the second program cycle.

In an example implementation, the third precharge voltage is greater than the second precharge voltage; the first precharge voltage, the second precharge voltage, and the third precharge voltage present a stepwise increasing trend or a linear increasing trend.

In an example implementation, the operation method further comprises: applying a first voltage to a word line coupled with a target memory cell in the precharge stage of the first program cycle; and applying a second voltage to the word line coupled with the target memory cell in the precharge stage of the second program cycle, wherein the second voltage is greater than the first voltage.

In an example implementation, the memory array further comprises a first word line group adjacent to the word line coupled with the target memory cell; the word line coupled with the target memory cell is located between the conductive line and the first word line group, the first word line group comprises at least one first word line and at least one second word line, the first word line is close to the word line coupled with the target memory cell, and the second word line is away from the word line coupled with the target memory cell; the operation method further comprises at least one of: applying a third voltage to the first word line in the precharge stage of the first program cycle, wherein the third voltage is less than or equal to the first voltage; or applying a fourth voltage to the first word line in the precharge stage of the second program cycle, wherein the fourth voltage is less than or equal to the second voltage, and the fourth voltage is greater than the third voltage.

In an example implementation, the operation method further comprises at least one of: applying a fifth voltage to the second word line in the precharge stage of the first program cycle, wherein the fifth voltage is less than the third voltage; or applying a sixth voltage to the second word line in the precharge stage of the second program cycle, wherein the sixth voltage is less than the fourth voltage, and the sixth voltage is greater than the fifth voltage.

In an example implementation, the first program cycle comprises at least one first pulse stage arranged in sequence, and the second program cycle comprises at least one second pulse stage arranged in sequence; the applying a first precharge voltage to the conductive line in a precharge stage of a first program cycle, and applying a second precharge voltage to the conductive line in a precharge stage of a second program cycle following the first program cycle comprise: applying a corresponding first precharge voltage to the conductive line in each of the first pulse stages, and applying a corresponding second precharge voltage to the conductive line in each of the second pulse stages; in the first program cycle, a first precharge voltage applied in a first pulse stage arranged in the front in sequence is less than or equal to a first precharge voltage applied in a first pulse stage arranged behind in sequence; in the second program cycle, a second precharge voltage applied in a second pulse stage arranged in the front in sequence is less than or equal to a second precharge voltage applied in a second pulse stage arranged behind in sequence.

In an example implementation, at least one of: a plurality of first precharge voltages applied correspondingly in the plurality of first pulse stages arranged in sequence present a stepwise increasing trend or a linear increasing trend; or a plurality of second precharge voltages applied correspondingly in the plurality of second pulse stages arranged in sequence present a stepwise increasing trend or a linear increasing trend.

In an example implementation, the applying a first voltage to a word line coupled with a target memory cell in the precharge stage of the first program cycle and applying a second voltage to the word line coupled with the target memory cell in the precharge stage of the second program cycle comprises: applying a corresponding first voltage to the word line coupled with the target memory cell in each of the first pulse stages; and applying a corresponding second voltage to the word line coupled with the target memory cell in each of the second pulse stages, wherein in the first program cycle, a first voltage applied in a first pulse stage arranged in the front in sequence is less than or equal to a first voltage applied in a first pulse stage arranged behind in sequence; in the second program cycle, a second voltage applied in a first pulse stage arranged in the front in sequence is less than or equal to a second voltage applied in a second pulse stage arranged behind in sequence.

In an example implementation, at least one of: a plurality of first voltages applied correspondingly in the plurality of first pulse stages arranged in sequence present a stepwise increasing trend or a linear increasing trend; or a plurality of second voltages applied correspondingly in the plurality of second pulse stages arranged in sequence present a stepwise increasing trend or a linear increasing trend.

In an example implementation, the memory array further comprises a second word line group, the second word line group comprises at least one third word line, and the second word line group is adjacent to the word line coupled with the target memory cell and located between the word line coupled with the target memory cell and the conductive line; the operation method further comprises: applying a seventh voltage to the third word line in the precharge stage of the first program cycle; and applying an eighth voltage to the third word line in the precharge stage of the second program cycle, wherein the seventh voltage is less than the eighth voltage.

In an example implementation, the memory array further comprises a third word line group, the third word line group comprises at least one fourth word line, and the third word line group is located between the second word line group and the conductive line; the operation method further comprises: connecting the fourth word line to a ground voltage in the precharge stage of the first program cycle and the precharge stage of the second program cycle.

In an example implementation, the operation method further comprises: applying a first program voltage to the word line coupled with the target memory cell in a program voltage application stage of the first program cycle; and applying a second program voltage to the word line coupled with the target memory cell in a program voltage application stage of the second program cycle, wherein the second program voltage is greater than the first program voltage.

In an example implementation, the conductive line comprises the common source line, and the memory array further comprises a bit line coupled with the other end of the memory cell string; the operation method further comprises: applying a program inhibit voltage to bit lines other than a bit line coupled with the target memory cell in the precharge stage and the program voltage application stage of the first program cycle and in the precharge stage and the program voltage application stage of the second program cycle.

In a fourth aspect, examples of the present disclosure provide a computer readable storage medium storing a computer program which, when executed, may implement the operation method of any one of above implementations.

### BRIEF DESCRIPTION OF THE DRAWINGS

FIG. 1 is a schematic diagram of an example system having a memory system provided by examples of the present disclosure.

FIG. 2 is a schematic diagram of an example memory card having a memory system provided by examples of the present disclosure.

FIG. 3 is a schematic diagram of an example solid state drive having a memory system provided by examples of the present disclosure.

FIG. 4 is a schematic diagram of an example memory device comprising a peripheral circuit provided by examples of the present disclosure.

FIG. 5 is a schematic sectional diagram of a memory array comprising a memory cell string provided by examples of the present disclosure.

FIG. 6 is a schematic diagram of an example memory device comprising a memory array and a peripheral circuit provided by examples of the present disclosure.

FIG. 7 is a schematic structural diagram of a memory device provided by examples of the present disclosure.

FIG. 8 is a schematic diagram of a relationship between the number of memory cells and a threshold voltage provided by examples of the present disclosure.

FIG. 9 is a flow diagram of an operation method provided by examples of the present disclosure.

FIG. 10 is a schematic diagram of dividing a program process into a plurality of program cycles provided by examples of the present disclosure.

FIG. 11 is a schematic diagram of a voltage application situation in an incremental step pulse program process provided by examples of the present disclosure.

FIG. 12 is a schematic diagram I of a voltage waveform change provided by examples of the present disclosure.

FIG. 13 is a schematic diagram of a waveform of channel potentials at corresponding positions in a channel in a precharge stage provided by examples of the present disclosure.

FIG. 14 is a schematic diagram of relationships of a precharge voltage with respect to the Fowler-Nordheim tunneling effect and the hot carrier injection effect provided by examples of the present disclosure.

FIG. 15 is a schematic diagram of a waveform of channel potentials at corresponding positions in a channel in a boosting stage provided by examples of the present disclosure.

FIG. 16 is a schematic diagram of a relationship of precharge voltages in different program cycles provided by examples of the present disclosure.

FIG. 17 is a schematic diagram II of a voltage waveform change provided by examples of the present disclosure.

FIG. 18 is a schematic diagram III of a voltage waveform change provided by examples of the present disclosure.

### DETAILED DESCRIPTION

Example implementations disclosed by the present disclosure will be described below in more details with reference to the drawings. Although the example implementations of the present disclosure are shown in the drawings, it is to be understood that the present disclosure may be achieved in various forms which should not be limited by implementations as set forth herein. Rather, these implementations are provided for a more thorough understanding of the present disclosure, and can fully convey the scope disclosed by the present disclosure to those skilled in the art.

In the following description, numerous details are presented to provide a more thorough understanding of the present disclosure. However, it is apparent to those skilled in the art that the present disclosure may be practiced without one or more of these details. In other examples, in order to avoid confusing with the present disclosure, some technical features well-known in the art are not described; that is, not all features of actual examples are described herein, and well-known functions and structures are not described in detail.

In the drawings, like reference numerals denote like elements throughout.

It is to be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if a device in the drawings is turned over, then an element or a feature described as being “below other elements”, or “under other elements”, or “beneath other elements” will be orientated to be “above” the other elements or features. Thus, the example terms “below” and “beneath” may comprise both upper and lower orientations. The device may be orientated otherwise (rotated by 90 degrees or other orientations), and the spatially descriptive terms used herein are interpreted accordingly.

The terms used herein are only intended to describe the examples, and are not used as limitations of the present disclosure. As used herein, unless otherwise indicated expressly in the context, “a”, “an” and “the” in a singular form are also intended to comprise a plural form. It is also to be understood that the terms “comprised of” and/or “comprise”, when used in this specification, determine the presence of the stated feature, integer, step, operation, element and/or component, but do not preclude the presence or addition of one or more of other features, integers, steps, operations, elements, components, and/or groups. As used herein, the term “and/or” comprises any and all combinations of related items listed.

A memory system in the examples of the present disclosure includes, but is not limited to, a memory system of a three-dimensional NAND memory. For ease of understanding, the memory system provided by the present disclosure is described by using the memory system comprising the three-dimensional NAND memory as an example.

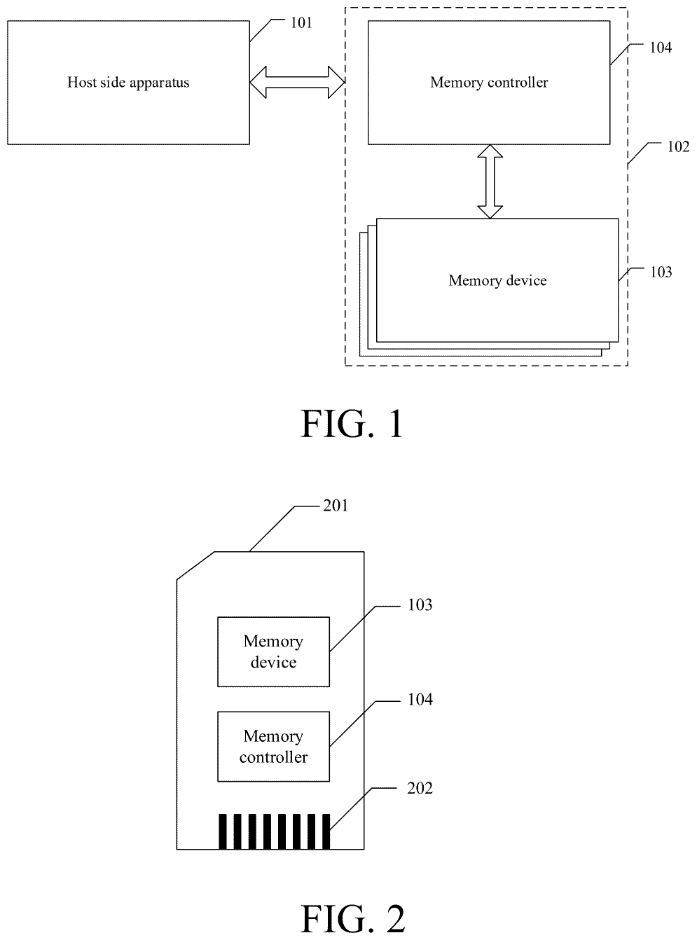

FIG. 1 is a schematic diagram of an example system having a memory system provided by examples of the present disclosure. In the examples of the present disclosure, the system 100 may be a mobile phone, a desktop computer, a laptop computer, a tablet computer, a vehicle computer, a game console, a printer, a positioning apparatus, a wearable electronic apparatus, a smart sensor, a Virtual Reality (VR) apparatus, an Augmented Reality (AR) apparatus or any other suitable electronic apparatuses having memories therein. As shown in FIG. 1, the system 100 may comprise a host side apparatus 101 and a memory system 102, and the memory system 102 may comprise one or more memory devices 103 and a memory controller 104. The host side apparatus 101 may comprise a processor of an electronic apparatus, e.g., a Central Processing Unit (CPU) or a System on Chip (SoC) (e.g., an Application Processor (AP)). The host side apparatus 101 may be configured to send or receive data to or from the memory system 102.

In some implementations, the memory controller 104 is coupled to the memory devices 103 and the host side apparatus 101 and configured to control the memory devices 103. The memory controller 104 can manage data stored in the memory devices 103 and communicate with the host side apparatus 101. In some implementations, the memory controller 104 is designed for operating in a low duty-cycle environment such as a Secure Digital Card, a Compact Flash Card (CFC), or a Universal Serial Bus (USB) flash drive, or operating in other media for use in electronic apparatuses, such as a personal computer, a digital camera, and a mobile phone, etc. In some other implementations, the memory controller 104 is designed for operating in a high duty-cycle environment, such as a Solid State Drive or an Embedded Multi-Media Card (eMMC).

In some examples, the memory controller 104 and the one or more memory devices 103 can be integrated into various types of storage apparatuses. That is, the memory system 102 can be implemented and packaged into different types of terminal electronic products.

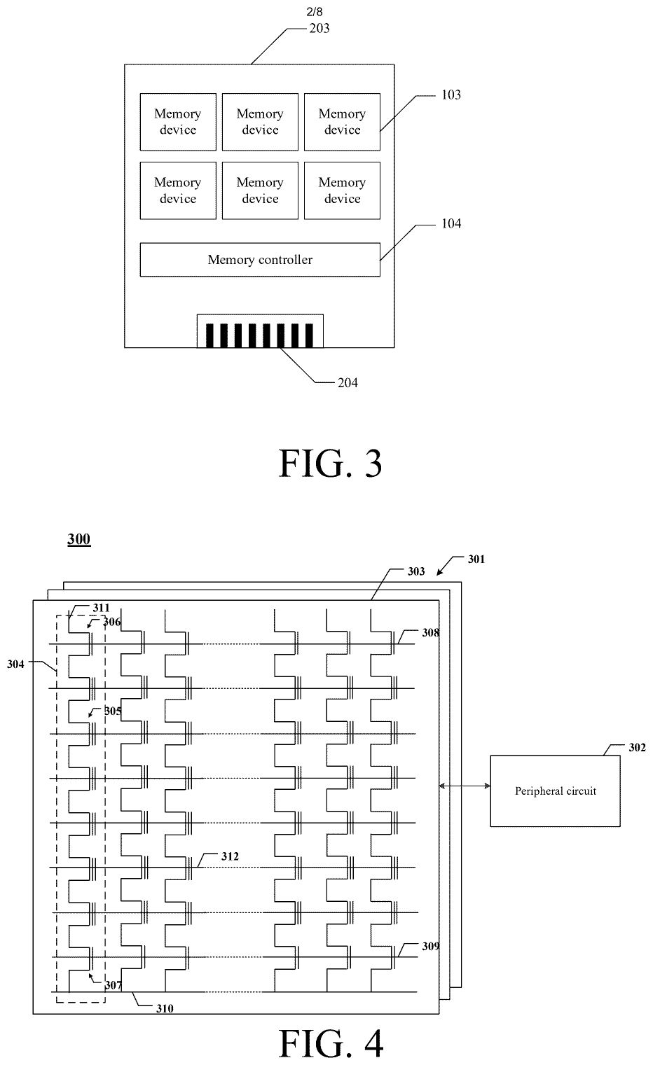

In one example as shown in FIG. 2, the memory controller 104 and a single memory device 103 may be integrated into a memory card 201. The memory card 201 may be one of a Compact Flash Card, a Smart Media Card (SMC), a Memory Stick (MS), a Multi-Media Card (MMC) such as an RS-MMC, an MMCmicro, and an eMMC, etc., a Secure Digital Card such as a Mini SD Card, a Micro SD card, and an SDHC card, etc., and a universal flash card. The memory card 201 may further comprise a memory card connector 202 that couples the memory card 201 with a host side apparatus (e.g., the host side apparatus 101 in FIG. 1). In another example as shown in FIG. 3, the memory controller 104 and a plurality of memory devices 103 may be integrated into an SSD 203. The SSD 203 may further comprise an SSD connector 204 that couples the SSD 203 with a host side apparatus (e.g., the host side apparatus 101 in FIG. 1). In some implementations, at least one of a storage capacity or an operation speed of the SSD 203 are greater than at least one of a storage capacity or an operation speed of the memory card 201.

FIG. 4 is a schematic circuit diagram of an example memory device 300 comprising a peripheral circuit provided by examples of the present disclosure. The memory device 300 may be an example of the memory device 103 in FIG. 1. The memory device 300 may comprise a memory array 301 and a peripheral circuit 302 coupled to the memory array 301. Taking the memory array 301 being a three-dimensional NAND memory array as an example for illustration, memory cells 305 are NAND memory cells, and the memory cells 305 are provided in an array of memory cell strings 304, with each memory cell string 304 extending perpendicularly above a substrate (not shown). In some implementations, each memory cell string 304 comprises a plurality of memory cells 305 coupled in series and stacked perpendicularly. Each memory cell 305 may maintain a continuous analog value, such as a voltage or charge, which depends on the number of electrons trapped within a region of the memory cell 305. Each memory cell 305 may be either a floating gate memory cell comprising a floating gate transistor, or a charge trap memory cell comprising a charge trap transistor.

A data writing principle of the memory cell is introduced below with a floating gate memory cell as an example. During writing of data to the memory cell, a program voltage may be loaded to a control gate of the floating gate field effect transistor to cause electrons in a channel of the floating gate field effect transistor to tunnel to the floating gate. The number of electrons tunneling to the floating gate can be controlled by controlling a magnitude of the program voltage, so as to control a magnitude of a threshold voltage Vth of the floating gate field effect transistor. Typically, if the amount of charge stored in the floating gate is larger, then the threshold voltage Vth of the floating gate field effect transistor is higher. It may be understood that floating gate field effect transistors with different threshold voltages Vth require different voltages to be loaded to control gates of the floating gate field effect transistors for controlling the floating gate field effect transistors to be on. Therefore, the magnitude of the threshold voltage Vth of the floating gate field effect transistor may reflect content of data stored in the memory cell.

In some implementations, each memory cell 305 is a Single Level Cell (SLC) that has two possible memory states and thus can store one bit of data. For example, a first memory state “0” may correspond to a first voltage range, and a second memory state “1” may correspond to a second voltage range. In some implementations, each memory cell 305 is a multiple level cell capable of storing more than a single bit of data in four or more memory states, e.g., a Multiple Level Cell (MLC) that stores two bits per cell, a Triple Level Cell (TLC) that stores three bits per cell, or a Quad Level Cell (QLC) that stores four bits per cell.

As shown in FIG. 4, each memory cell string 304 may comprise a Bottom Select Transistor (BST) 307 at a source terminal thereof and a Top Select Transistor (TST) 306 at a drain terminal thereof. The bottom select transistor 307 and the top select transistor 306 may be configured to activate the selected memory cell string 304 during read and program operations. In some implementations, sources of the memory cell strings 304 in the same memory block 303 may be coupled through a Common Source Line (CSL) 310. In other words, all the memory cell strings 304 in the same memory block 303 have an Array Common Source (ACS). According to some implementations, the top select transistor 306 of each memory cell string 304 is coupled to a respective Bit Line (BL) 311, wherein data can be read from or written to the bit line 311 via an output bus (not shown). In some implementations, each memory cell string 304 is configured to be selected or unselected by applying a select voltage (e.g., above a threshold voltage of the top select transistor 306) or an unselect voltage (e.g., 0 V) to the respective top select transistor 306 via one or more Top Select Lines (TSLs) 308 and/or by applying a select voltage (e.g., above a threshold voltage of the bottom select transistor 307) or an unselect voltage (e.g., 0 V) to the respective bottom select transistor 307 via one or more Bottom Select lines (BSLs) 309.

As shown in FIG. 4, memory cell strings 304 may be organized into a plurality of memory blocks 303, and each of the plurality of memory blocks 303 may have a common source line 310. In some implementations, each memory block 303 is a basic data unit for an erase operation, i.e., all the memory cells 305 on the same memory block 303 are erased at the same time. In order to erase the memory cells 305 in the selected memory block, the common source line 310 coupled to the selected memory block as well as unselected memory blocks that are in the same plane as the selected memory block may be biased with an erase voltage. It is to be understood that in some examples, the erase operation may be performed at a half memory block level, a quarter memory block level, or a level having any suitable number of memory blocks or any suitable fraction of a memory block. The memory cells 305 of adjacent ones of the memory cell strings 304 may be coupled through a word line 312, and the word line 312 selects which row of memory cells 305 affected by the read or program operation.

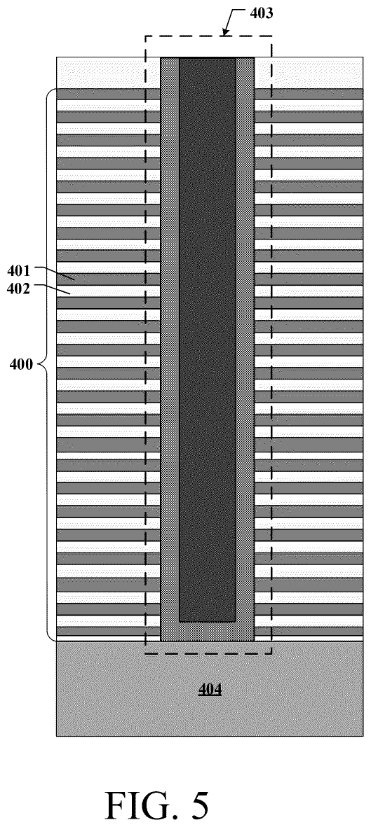

FIG. 5 is a schematic sectional diagram of a memory array comprising a memory cell string provided by examples of the present disclosure. As shown in FIG. 5, the memory array may comprise a stacked structure 400, and the stacked structure 400 comprises a plurality of gate layers 401 and a plurality of insulation layers 402 that are disposed as being stacked in sequence and alternately, and a channel structure 403 perpendicularly penetrating through the gate layers 401 and the insulation layers 402. The gate layers 401 and the insulation layers 402 may be stacked alternately, with two adjacent ones of the gate layers 401 being separated by one insulation layer 402. The number of memory cells included in the memory array is primarily related to the number of pairs of the gate layers 401 and the insulation layers 402 in the stacked structure 400.

A composition material of the gate layers 401 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 401 comprises a metal layer, e.g., a tungsten layer. In some implementations, each gate layer 401 comprises a doped polysilicon layer. The plurality of gate layers 401 surround one channel structure 403 to constitute one memory cell string. The gate layer 401 at the top of the stacked structure 400 may extend laterally as a top select gate line, the gate layer 401 at the bottom of the stacked structure 400 may extend laterally as a bottom select gate line, and the gate layers 401 that extend laterally between the top select gate line and the bottom select gate line may act as word line layers.

In some examples, the stacked structure 400 may be disposed on a substrate 404. The substrate 404 may include silicon (e.g., monocrystalline silicon), silicon germanium (SiGe), gallium arsenide (GaAs), germanium (Ge), silicon on insulator (SOI), germanium on insulator (GOI), or any other suitable material.

It is to be noted that in some other examples, the memory array may comprise only the stacked structure 400 and comprise no substrate, and whether the memory array comprises the substrate is not limited in the present disclosure.

In some implementations, the channel structure 403 comprises a functional layer, a channel layer, and an insulation filling layer. In some implementations, the channel layer includes silicon, e.g., polysilicon. In some implementations, the functional layer is a composite dielectric layer comprising a tunneling layer, a storage layer (also referred to as a “charge trap/storage layer”), and a blocking layer. The channel structure 403 may have a cylindrical shape (e.g., a pillar shape). According to some implementations, the channel layer, the tunneling layer, the storage layer, and the blocking layer are arranged radially from a center toward an outer surface of a pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In an example, the functional layer may include a composite layer of silicon oxide/silicon oxynitride/silicon oxide (ONO).

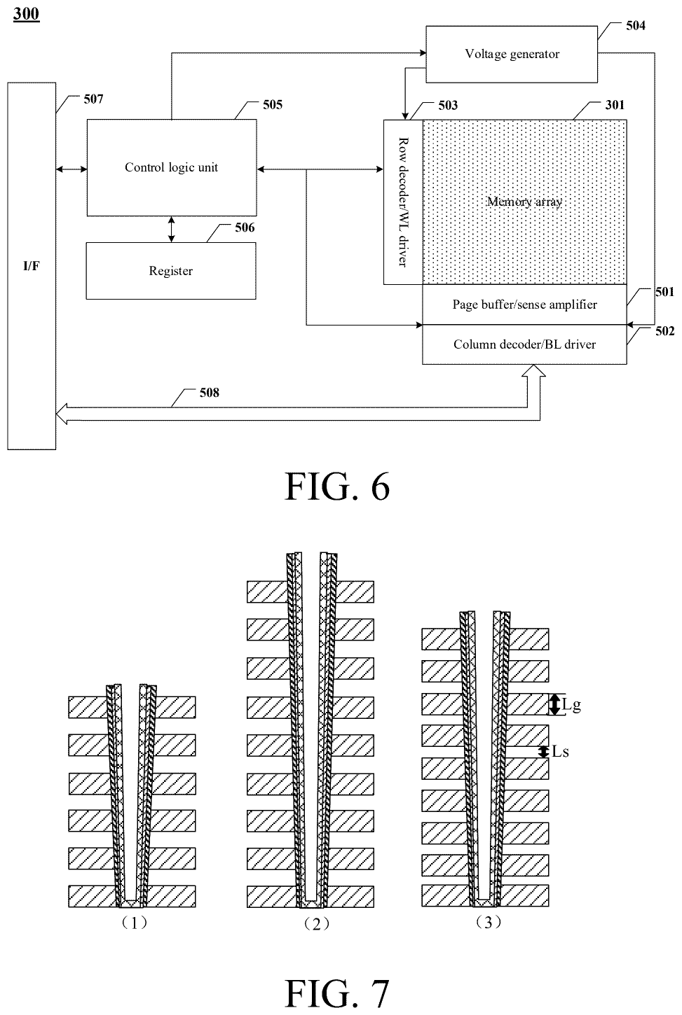

Referring back to FIG. 4, the peripheral circuit 302 may be coupled to the memory array 301 through bit lines 311, word lines 312, the common source line 310, the bottom select line 309, and the top select line 308. The peripheral circuit 302 may include any suitable analog, digital, and hybrid signal circuits for implementing operations on the memory array 301 by applying at least one of voltage signals or current signals to each target memory cell 305 and sensing at least one of voltage signals or current signals from each target memory cell 305 via the bit lines 311, the word lines 312, the common source line 310, the bottom select line lines 309, and the top select line 308. The peripheral circuit 302 may include various types of peripheral circuits formed using a metal-oxide-semiconductor technology. For example, FIG. 6 shows some example peripheral circuits. The peripheral circuit 302 comprises a page buffer/sense amplifier 501, a column decoder/bit line driver 502, a row decoder/word line driver 503, a voltage generator 504, a control logic unit 505, a register 506, a flash interface 507, and a data bus 508. It is to be understood that, in some examples, an additional peripheral circuit not shown in FIG. 6 may also be included.

The page buffer/sense amplifier 501 may be configured to read data from the memory array 301 and program (write) data to the memory array 301 according to control signals from the control logic unit 505. In an example, the page buffer/sense amplifier 501 may store one page of program data (write data) to be programmed into the memory array 301. In another example, the page buffer/sense amplifier 501 may perform a program verify operation to ensure that data is properly programmed into the memory cells that are coupled to a selected word line. In yet another example, the page buffer/sense amplifier 501 may also sense a low power signal from the bit lines that represents a data bit stored in the memory cell, and amplify a small voltage swing to a recognizable logic level in a read operation. The column decoder/bit line driver 502 may be configured to be controlled by the control logic unit 505 and select one or more memory cell strings by applying bit line voltages generated from the voltage generator 504.

The row decoder/word line driver 503 may be configured to be controlled by the control logic unit 505, select/unselect the memory block of the memory array 301, and select/unselect the word line of the memory block. The row decoder/word line driver 508 may be further configured to drive the word line using a word line voltage generated from the voltage generator 504. In some implementations, the row decoder/word line driver 503 may also select/unselect and drive the bottom select line and the top select line. As described below in detail, the row decoder/word line driver 503 is configured to perform the program operation on the memory cells that are coupled to (one or more) selected word lines. The voltage generator 504 may be configured to be controlled by the control logic unit 505 and generate the word line voltage (e.g., a read voltage, a program voltage, a precharge voltage, a pass voltage, a local voltage, a verify voltage, etc.), the bit line voltage, and a source line voltage to be supplied to the memory array 301.

The control logic unit 505 may be coupled to each peripheral circuit as described above and configured to control operations of each peripheral circuit. The register 506 may be coupled to the control logic unit 505 and comprise a state register, a command register, and an address register, so as to store state information, command operation code (OP code), and command address for controlling the operations of each peripheral circuit. The flash interface 507 may be coupled to the control logic unit 505, and act as a control buffer to buffer and relay a control command received from the host side apparatus (not shown) to the control logic unit 505 and buffer and relay state information received from the control logic unit 505 to the memory controller. The flash interface 507 may also be coupled to the column decoder/bit line driver 502 via the data bus 508 and act as a data I/O interface and a data buffer to buffer and relay the data to and from the memory array 301.

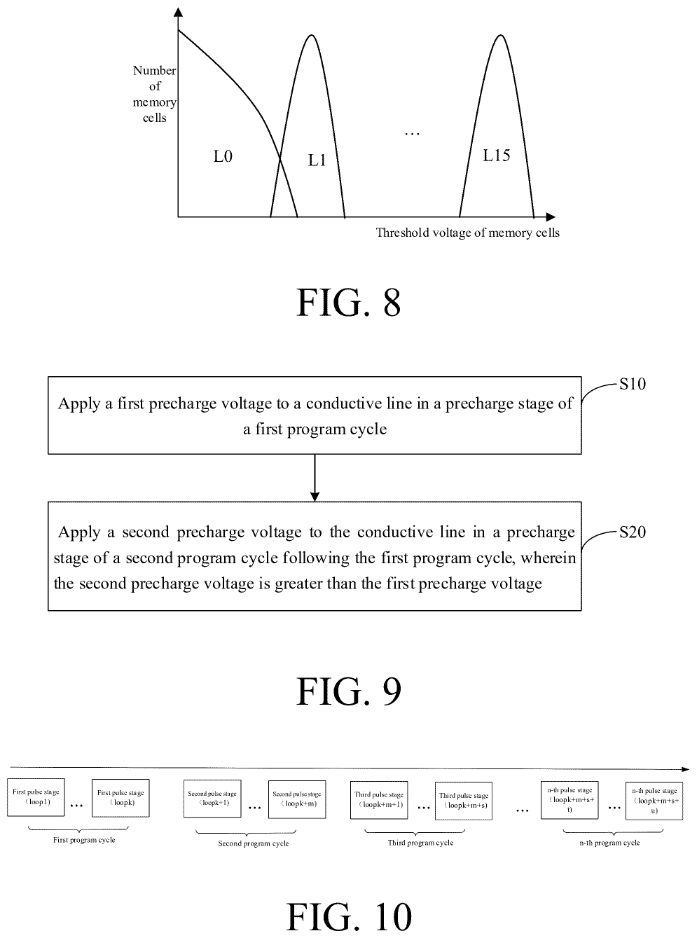

In pursuit of a higher storage density, the three-dimensional flash memory has increasingly more stacked layers therein, and the memory cell has increasingly more memory bits, including the TLC that may implement three-bit storage, and the QLC that may implement four-bit storage, etc. For the QLC, one page is divided into 16 states, causing program disturbance during a program process to be more serious. In order to reduce costs, referring to FIG. 7, as shown in parts (1) to (2), the number of stacked layers of the three-dimensional flash memory increases continuously, and in order to reduce channel etch difficulty, as shown in parts (2) to (3), the ratio (Ls/Lg) of a distance Ls between the word line layers to a thickness Lg of the word line layer in the stacked structure decreases continuously. As Ls/Lg decreases continuously and the number of stacked layers increases continuously, Fowler-Nordheim (FN) tunneling and Hot Carrier Injection become increasingly serious, thereby causing serious program disturbance. As shown in FIG. 8, a width of a threshold voltage distribution of a state L0 (erased state) is caused to expand, leading to a great challenge to the reliability of the flash memory. How to suppress the program disturbance and widen a threshold voltage window becomes an urgent problem to be solved currently.

The present disclosure provides an operation method of a memory device. FIG. 9 is a flow diagram of the operation method provided by examples of the present disclosure. As shown in FIG. 9, the operation method of a memory device comprises the following operations: operation S10: applying a first precharge voltage to a conductive line in a precharge stage of a first program cycle; and operation S20: applying a second precharge voltage to the conductive line in a precharge stage of a second program cycle following the first program cycle, wherein the second precharge voltage is greater than the first precharge voltage.

In the examples of the present disclosure, the first precharge voltage is applied to the conductive line in the precharge stage of the first program cycle, and the second precharge voltage is applied to the conductive line in the precharge stage of the second program cycle following the first program cycle, wherein the second precharge voltage is greater than the first precharge voltage, such that the Fowler-Nordheim tunneling effect and hot carrier effect during the entire program process may be improved effectively, thereby suppressing the program disturbance effectively and improving the performance of the memory device.

In some examples, the three-dimensional flash memory device is programmed mainly using an Incremental Step Pulse Program (ISPP) method. During the program process, rather than being applied in one time, a program voltage is applied by increasing the program voltage step by step incrementally, until reaching the requirement for programming. As shown in FIG. 10, the program process comprises a plurality of program cycles, such as a first program cycle, a second program cycle, a third program cycle, . . . , and an n-th program cycle, with each program cycle comprising at least one pulse stage, and each pulse stage comprising a verify stage, a precharge stage, and a program voltage application stage.

It is to be noted that, the number of pulse stages contained in each program cycle may be the same or different from each other. In an example, the number of pulse stages contained in the first program cycle may be greater than or equal to or less than the number of pulse stages contained in the second program cycle.

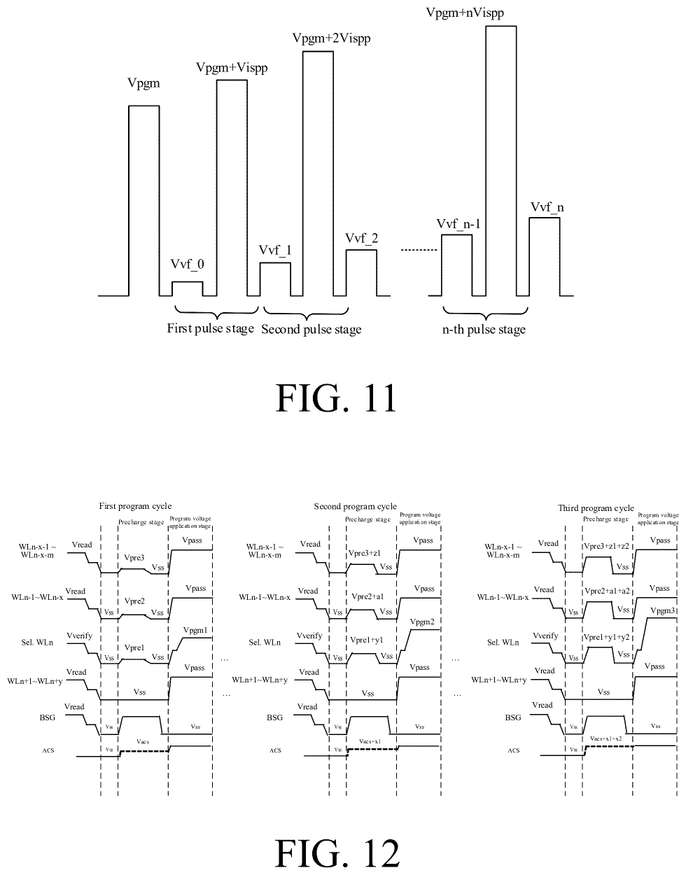

FIG. 11 shows a schematic diagram of the ISPP programming provided by examples of the present disclosure. As shown in FIG. 11, during the program process, an initial program voltage (Vpgm) is first applied to a word line coupled with a target memory cell; then whether the initial program voltage reaches a required program voltage is verified in a first pulse stage, and if not, a voltage step Vispp is added to the initial program voltage to obtain a program voltage (Vpgm+Vispp) and the programming voltage (Vpgm+Vispp) is applied to the word line coupled to the target memory cell; and whether the program voltage (Vpgm+Vispp) reaches the required program voltage is verified in a second pulse stage. The above process is performed cyclically, and the program does not stop until a program voltage applied to the word line coupled with the target memory cell reaches the required program voltage. It is to be noted that FIG. 11 does not show a precharge stage in each pulse stage.

In some examples, the memory device comprises a memory array and a peripheral circuit coupled with the memory array, wherein the memory array comprises a plurality of memory cell strings and the conductive line coupled with one end of a memory cell string.

In some examples, the conductive line comprises a bit line or a common source line.

In some examples, the program may be forward program or reverse program. In an example, the forward program may refer to a program order from bottom to top, and the reverse program may refer to a program order from top to bottom, and the present disclosure is not limited thereto. In the forward program, the abovementioned conductive line may be the bit line, i.e., precharge may be performed through a bit line end; in the reverse program, the abovementioned conductive line may be the common source line, i.e., precharge may be performed through the common source line.

An example illustration is performed below with an example where the program order indicates the reverse program and the precharge is performed through the common source line ACS.

It is to be noted that in both the forward program and the reverse program, WLs may be numbered from WL0 to WLn+x+m (assuming that the memory device comprises a total of n+y+1 word lines), and serial numbers of the word lines arranged from top to bottom in the stacked structure are consecutive, wherein program operations are performed in sequence from a WL with a small serial number to a WL with a large serial number, and WL0 is a WL where the program is started, i.e., in the same memory cell string, the program is performed in sequence from a memory cell coupled with the WL with a small serial number to a memory cell coupled with the WL with a large serial number. In the reverse program as shown in FIG. 12, the program is started at WL0, and WL0 is closest to the top select line (TSL) among the plurality of word lines in the stacked structure. In forward program as shown in FIG. 18, the program is started at WL0, and WL0 is closest to the bottom select line (BSL) among the plurality of word lines in the stacked structure. In both examples shown in FIG. 12 and FIG. 18, Sel WLn is the word line coupled with the target memory cell.

As shown in FIG. 12, the first precharge voltage Vacs is applied to the common source line in the precharge stage of the first program cycle, and the second precharge voltage Vacs+x1 is applied to the common source line in the precharge stage of the second program cycle following the first program cycle.

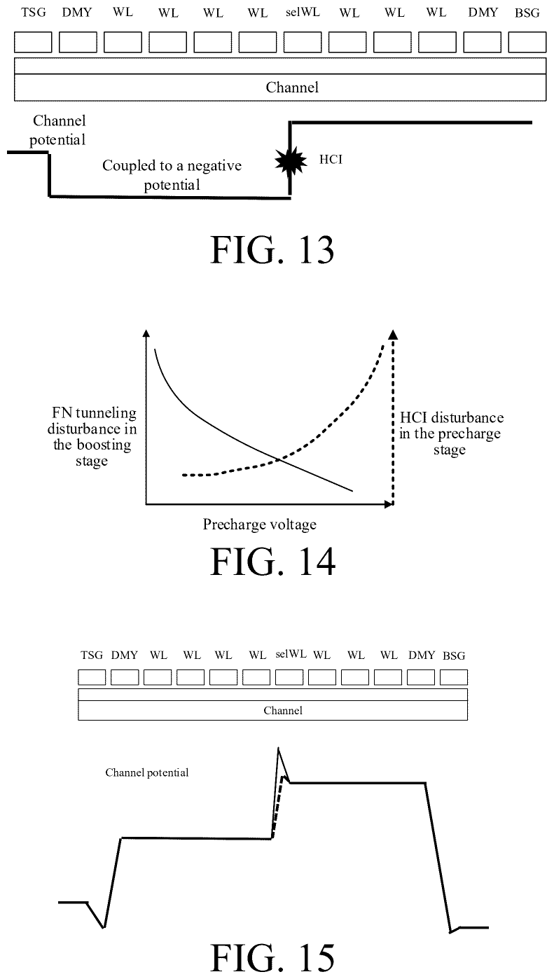

FIG. 13 is a schematic diagram of a waveform of channel potentials at corresponding positions in a channel in the precharge stage. FIG. 14 is a schematic diagram of relationships of the precharge voltage with respect to the Fowler-Nordheim tunneling effect and the hot carrier injection effect, wherein a solid line is a curve representing a relationship of the precharge voltage with respect to the Fowler-Nordheim tunneling effect, and a dashed line is a curve representing a relationship of the precharge voltage with respect to the hot carrier injection effect. As shown in FIG. 13 and FIG. 14, HCI disturbance becomes increasingly serious during the precharge stage of the pulse stage, and if a larger precharge voltage is applied to the common source line or bit line during the precharge stage, then the HCI disturbance is more serious. FIG. 15 is a schematic diagram of a waveform of channel potentials at corresponding positions in the channel in a boosting stage, wherein the dashed line is a schematic diagram of the channel potentials in the case of a low precharge voltage, and the solid line is a schematic diagram of the channel potentials in the case of a high precharge voltage. As shown in FIG. 15, in the boosting stage, it is desired that a boosted potential of the channel near the word line coupled with the target memory cell reaches a certain degree, for the purpose of reducing a word line-channel voltage difference and reducing L0 disturbance caused by the FN tunneling. The program disturbance caused by the FN tunneling is more serious in a program cycle arranged behind in sequence, and it is generally better to required to have a higher precharge voltage in the precharge stage. However, as shown in FIG. 14 and FIG. 15, if the precharge voltage is higher, then the FN disturbance is more serious. For the program disturbance, the HCI is easy to occur if local boosting is excessively high, and the FN is easy to occur if the local boosting is insufficient, and such two mechanisms are balanced with each other. As shown in FIG. 14, the HCI disturbance in the precharge stage and the disturbance caused by the FN tunneling in the boosting stage have opposite requirements for the precharge voltage. Since the disturbance caused by the FN tunneling is most serious in the several program cycles later, in the examples of the present disclosure, a high precharge voltage is applied to the common source line or bit line in the precharge stage in a program cycle arranged behind in sequence, and a low precharge voltage is used in a program cycle arranged in the front in sequence, thereby effectively improving the program disturbance caused by the FN tunneling effect and the hot carrier effect during the entire program process.

A sequential arrangement in the examples of the present disclosure may be understood as a chronological arrangement.

In some examples, as shown in FIG. 12, the operation method further comprises: applying a third precharge voltage Vacs+x1+x2 to the conductive line in a precharge stage of a third program cycle following the second program cycle.

It is to be noted that above three program cycles are merely used as examples for illustration in the present disclosure, and the examples of the present disclosure impose no limitations on the number of program cycles and may also comprise more program cycles. The precharge voltage applied in the program cycle arranged behind in sequence is greater than the precharge voltage applied in the program cycle arranged in the front in sequence.

In some examples, the third precharge voltage is greater than the second precharge voltage; the first precharge voltage, the second precharge voltage, and the third precharge voltage present a stepwise increasing trend or a linear increasing trend.

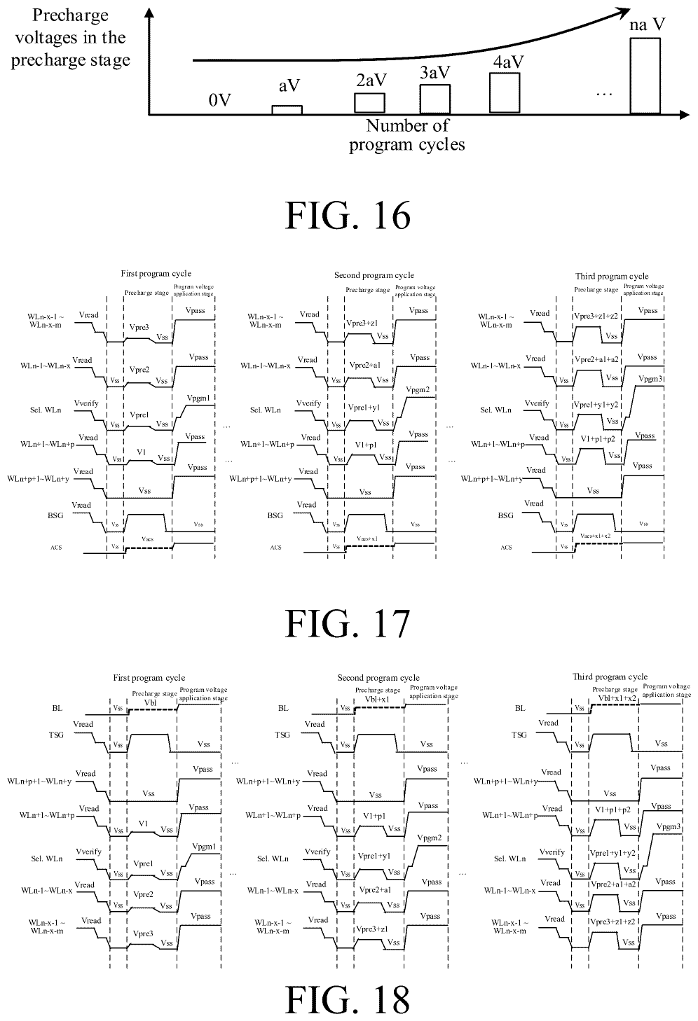

FIG. 16 is a schematic diagram of a relationship of precharge voltages in different program cycles. As shown in FIG. 16, magnitudes of precharge voltages applied in pulse stages in one program cycle may be the same, and precharge voltages of different program cycles during the program process may present the linear increasing trend.

In some examples, the first program cycle comprises at least one first pulse stage arranged in sequence, and the second program cycle comprises at least one second pulse stage arranged in sequence; the applying a first precharge voltage to the conductive line in a precharge stage of a first program cycle, and applying a second precharge voltage to the conductive line in a precharge stage of a second program cycle following the first program cycle comprise: applying a corresponding first precharge voltage to the conductive line in each of the first pulse stages, and applying a corresponding second precharge voltage to the conductive line in each of the second pulse stages; in the first program cycle, a first precharge voltage applied in a first pulse stage arranged in the front in sequence is less than or equal to a first precharge voltage applied in a first pulse stage arranged behind in sequence; in the second program cycle, a second precharge voltage applied in a second pulse stage arranged in the front in sequence is less than or equal to a second precharge voltage applied in a second pulse stage arranged behind in sequence.

The first program cycle may comprise one first pulse stage or may comprise a plurality of first pulse stages; the second program cycle may comprise one first pulse stage or may comprise a plurality of first pulse stages. Each of the first pulse stages comprises a precharge stage and a program voltage application stage. When the first program cycle comprises a plurality of first pulse stages, the corresponding first precharge voltage is applied in each first pulse stage, and in the first program cycle, the first precharge voltage applied correspondingly in the first pulse stage arranged chronologically in the front may be less than or equal to the first precharge voltage applied correspondingly in the first pulse stage arranged chronologically behind.

It may be understood that in the solution provided by the examples of the present disclosure, the precharge voltages of all the pulse stages in one program cycle may be equal. The precharge voltages of all the pulse stages in one program cycle may also be different, with a precharge voltage of a pulse stage arranged chronologically behind being greater than a precharge voltage of a pulse stage arranged chronologically in the front. It is also possible that part of the precharge voltages of all the pulse stages in one program cycle are the same while the other precharge voltages are different.

In some examples, at least one of: a plurality of first precharge voltages applied correspondingly in the plurality of first pulse stages arranged in sequence present a stepwise increasing trend or a linear increasing trend; or a plurality of second precharge voltages applied correspondingly in the plurality of second pulse stages arranged in sequence present a stepwise increasing trend or a linear increasing trend.

It may be understood that when the precharge voltages of all the pulse stages in one program cycle are different, the precharge voltages applied correspondingly in the plurality of pulse stages in one program cycle may be set as presenting either the stepwise increasing trend or the linear increasing trend.

In some examples, the operation method further comprises: applying a first voltage to a word line coupled with a target memory cell in the precharge stage of the first program cycle; and applying a second voltage to the word line coupled with the target memory cell in the precharge stage of the second program cycle, wherein the second voltage is greater than the first voltage.

As shown in FIG. 12, the first voltage (Vpre1) is applied to the word line (Sel WLn) coupled with the target memory cell in the first program cycle, and the second voltage (Vpre1+y1) is applied to the Sel WLn in the precharge stage of the second program cycle.

In some examples, as shown in FIG. 12, the method further comprises: applying Vpre1+y1+y2 to the Sel WLn in the precharge stage of the third program cycle.

In some examples, at least one of: a plurality of first voltages applied correspondingly in the plurality of first pulse stages arranged in sequence present a stepwise increasing trend or a linear increasing trend; or a plurality of second voltages applied correspondingly in the plurality of second pulse stages arranged in sequence present a stepwise increasing trend or a linear increasing trend.

It may be understood that in the examples of the present disclosure, in order to further improve the HCI disturbance in a precharge stage of a later program cycle, in an example of the present disclosure, different voltages are applied to the word line coupled with the target memory cell in different program cycles, and a voltage applied to the word line coupled with the target memory cell in the later program cycle is greater than a voltage applied to the word line coupled with the target memory cell in an earlier program cycle. The voltage applied to the word line coupled with the target memory cell changes following a change in the precharge voltage, such that a potential difference between the channel potential corresponding to the target memory cell and a channel potential corresponding to an unprogrammed memory cell may be reduced, thereby effectively improving the problem of HCI disturbance in the later program cycle.

In the examples of the present disclosure, the number of pulse stages contained in the first program cycle may be greater than the number of pulse stages contained in the second program cycle and the number of pulse stages contained in the third program cycle, and the plurality of precharge voltages applied correspondingly in the plurality of pulse stages contained in the first program cycle may be equal, in which case the increase of the precharge voltage may be considered as starting in several later pulse stages during the entire program process. In an example, the increase of the precharge voltage is started when the program reaches a certain programmed state. In some other examples, the increase of the precharge voltage and the increase of the voltage applied to the word line coupled with the target memory cell may be started simultaneously in the precharge stages of the several later pulse stages during the program process.

In some other examples, the number of pulse stages contained in the first program cycle may be equal to the number of pulse stages contained in the second program cycle and the number of pulse stages contained in the third program cycle, and the plurality of precharge voltages applied correspondingly in the plurality of pulse stages contained in the first program cycle may be equal, in which case the increase of the precharge voltage may be considered as being started in intermediate pulse stages during the entire program process. Furthermore, in this case, the plurality of precharge voltages applied correspondingly in the plurality of pulse stages contained in the second program cycle may be different, and in the second program cycle, a precharge voltage applied in a pulse stage arranged chronologically behind is greater than a precharge voltage applied in a pulse stage arranged in the front. An increase trend that may comprise the stepwise increasing trend or the linear increasing trend. The plurality of precharge voltages applied correspondingly in the plurality of pulse stages contained in the third program cycle may be different or equal.

In some examples, the applying a first voltage to a word line coupled with a target memory cell in the precharge stage of the first program cycle and applying a second voltage to the word line coupled with the target memory cell in the precharge stage of the second program cycle comprises: applying a corresponding first voltage to the word line coupled with the target memory cell in each of the first pulse stages; and applying a corresponding second voltage to the word line coupled with the target memory cell in each of the second pulse stages, wherein in the first program cycle, a first voltage applied in a first pulse stage arranged in the front in sequence is less than or equal to a first voltage applied in a first pulse stage arranged behind in sequence; in the second program cycle, a second voltage applied in a first pulse stage arranged in the front in sequence is less than or equal to a second voltage applied in a second pulse stage arranged behind in sequence.

In some examples, the memory array further comprises a first word line group adjacent to the word line coupled with the target memory cell; the word line coupled with the target memory cell is located between the conductive line and the first word line group, the first word line group comprises at least one first word line and at least one second word line, the first word line is close to the word line coupled with the target memory cell, and the second word line is away from the word line coupled with the target memory cell; the operation method further comprises at least one of: applying a third voltage to the first word line in the precharge stage of the first program cycle, wherein the third voltage is less than or equal to the first voltage; or applying a fourth voltage to the first word line in the precharge stage of the second program cycle, wherein the fourth voltage is less than or equal to the second voltage, and the fourth voltage is greater than the third voltage.

As shown in FIG. 12, the word line (Sel WLn) coupled with the target memory cell is located between the ACS and the first word line group (WLn−1 to WLn−x−m), and the first word line group comprises at least one first word line (WLn−1 to WLn−x) and at least one second word line (WLn−x−1 to WLn−x−m). At least one of: the third voltage (Vpre2) is applied to the WLn−1 to WLn−x in the precharge stage of the first program cycle, with Vpre2 being less than or equal to Vpre1; the fourth voltage (Vpre2+a1) is applied to the WLn−1 to WLn−x in the precharge stage of the second program cycle; or Vpre2+p1+a2 is applied to the WLn−1 to WLn−x in the precharge stage of the third program cycle.

It may be understood that in examples of the present disclosure, a voltage being applied to the WLn−1 to WLn−x in a precharge stage may reduce a potential difference between WLn and WLn−1, thereby reducing the HCI disturbance in the precharge stage. Furthermore, in the examples of the present disclosure, based on the voltage applied to the WLn that increases with the program cycles, the voltage applied to the WLn−1 to WLn−x also increases with the program cycles, to further reduce the potential difference between the WLn and the WLn−1, thereby further reducing the HCI disturbance in the precharge stage.

In some examples, the operation method further comprises at least one of: applying a fifth voltage to the second word line in the precharge stage of the first program cycle, wherein the fifth voltage is less than the third voltage; or applying a sixth voltage to the second word line in the precharge stage of the second program cycle, wherein the sixth voltage is less than the fourth voltage, and the sixth voltage is greater than the fifth voltage.

As shown in FIG. 12, at least one of: the fifth voltage (Vpre3) is applied to the second word line (WLn−x−1 to WLn−x−m) in the precharge stage of the first program cycle; the sixth voltage (Vpre3+z1) is applied to the WLn−x−1 to WLn−x−m in the precharge stage of the second program cycle; or Vpre3+z1+z2 is applied to the WLn−x−1 to WLn−x−m in the precharge stage of the third program cycle.

It may be understood that in the examples of the present disclosure, a voltage being applied to the WLn−x−1 to WLn−x−m in a precharge stage may reduce a potential difference between WLn−1 to WLn−x and WLn−x−1 to WLn−x−m, thereby reducing the HCI disturbance in the precharge stage. Furthermore, in the examples of the present disclosure, based on the voltage applied to the WLn−1 to WLn−x that increases with the program cycles, the voltage applied to the WLn−x−1 to WLn−x−m also increases with the program cycles, to further reduce the potential difference between the WLn−1 to WLn−x and the WLn−x−1 to WLn−x−m, thereby further reducing the HCI disturbance in the precharge stage.

In some examples, as shown in FIG. 12, a ground voltage Vss may be applied to WLn+1 to WLn+y in each of the precharge stage of the first program cycle, the precharge stage of the second program cycle, and the precharge stage of the third program cycle.

In some examples, the memory array further comprises a second word line group, the second word line group comprises at least one third word line, and the second word line group is adjacent to the word line coupled with the target memory cell and located between the word line coupled with the target memory cell and the conductive line; the operation method further comprises: applying a seventh voltage to the third word line in the precharge stage of the first program cycle; and applying an eighth voltage to the third word line in the precharge stage of the second program cycle, wherein the seventh voltage is less than the eighth voltage.

As shown in FIG. 17, the second word line group (WLn+1 to WLn+p) comprises at least one third word line, and the seventh voltage (V1) is applied to the third word line in the precharge stage of the first program cycle; and the eighth voltage (V1+p1) is applied to the third word line in the precharge stage of the second program cycle, and V1+p1+p2 is applied to the third word line in the precharge stage of the third program cycle.

In some examples, program methods include one-step program and multi-step program. The one-step program refers to a single ISPP program operation, wherein the single ISPP operation comprises a plurality of pulse stages, with a corresponding program voltage being applied in each pulse stage. The multi-step program refers to multiple ISPP operations, wherein each ISPP operation comprises a plurality of pulse stages, with a corresponding program voltage being applied in each pulse stage. The multi-step program may comprise a coarse program operation and a fine program operation. The coarse program operation may result in a coarse threshold voltage distribution. The fine program operation may finely narrow the threshold voltage distribution resulting from the coarse program operation. The coarse program operation may comprise a plurality of program cycles, with each program cycle comprising at least one pulse stage, and each pulse stage comprising a verify stage, a precharge stage, and a program voltage application stage; the fine program operation may also comprise a plurality of program cycles, with each program cycle comprising at least one pulse stage, and each pulse stage comprising a verify stage, a precharge stage, and a program voltage application stage. The multi-step program may cause a final threshold voltage distribution to be narrower and a spacing between states to be wider, such that the performance of the memory device may be improved.

In the multi-step program method of the examples of the present disclosure, different voltages may be applied to the third word line in different program cycles of each program step. In an example, in the coarse program (or fine program), a voltage applied to the third word line in a program cycle arranged in the front in sequence is less than a voltage applied to the third word line in a program cycle arranged behind in sequence, to reduce a potential difference between channel potentials corresponding to the word line coupled with the target memory cell and the third word line, thereby further reducing the HCI, suppressing the program disturbance, and improving the performance of the memory device.

In some examples, the memory array further comprises a third word line group, the third word line group comprises at least one fourth word line, and the third word line group is located between the second word line group and the conductive line; the operation method further comprises: connecting the fourth word line to a ground voltage in the precharge stage of the first program cycle and the precharge stage of the second program cycle.

As shown in FIG. 17, the third word line group (WLn+p+1 to WLn+y) comprises at least one fourth word line, and the fourth word line is connected to the ground voltage (Vss) in the precharge stage of the first program cycle, the precharge stage of the second program cycle, and the precharge stage of the third program cycle.

In some examples, as shown in FIG. 12, the operation method further comprises: applying a first program voltage (Vpgm1) to the word line coupled with the target memory cell in a program voltage application stage of the first program cycle; and applying a second program voltage (Vpgm2) to the word line coupled with the target memory cell in a program voltage application stage of the second program cycle, wherein the second program voltage is greater than the first program voltage.

In some examples, as shown in FIG. 12, the method further comprises: applying a third program voltage (Vpgm3) to the word line coupled with the target memory cell in a program voltage application stage of the third program cycle, with the third program voltage being greater than the second program voltage.

In some examples, the conductive line comprises the common source line, and the memory array further comprises a bit line coupled with the other end of the memory cell string; the operation method further comprises: applying a program inhibit voltage to bit lines other than a bit line coupled with the target memory cell in the precharge stage and the program voltage application stage of the first program cycle and in the precharge stage and the program voltage application stage of the second program cycle.

In some examples, as shown in FIG. 12, the method further comprises: applying a respective voltage to a Bottom Select Gate (BSG) in the precharge stage of the first program cycle, the precharge stage of the second program cycle, and the precharge stage of the third program cycle.

The example illustration is performed above with an example where the program order indicates the reverse program, the precharge is performed through the common source line ACS, and the conductive line is the ACS. A further illustration is performed below in conjunction with FIG. 18 with an example where the program order indicates the forward program, the precharge is performed through the BL, and the conductive line is the BL.

As shown in FIG. 18, the conductive line is the bit line (BL), the first precharge voltage Vb1 is applied to the BL in the precharge stage of the first program cycle, the second precharge voltage Vb1+x1 is applied to the BL in the precharge stage of the second program cycle, and the third precharge voltage Vb1+x1+x2 is applied to the BL in the precharge stage of the third program cycle, with Vb1<Vb1+x1<Vb1+x1+x2.

In some examples, as shown in FIG. 18, the method further comprises: applying a respective voltage to a Top Select Gate (TSG) in the precharge stage of the first program cycle, the precharge stage of the second program cycle, and the precharge stage of the third program cycle.

In some examples, as shown in FIG. 18, the method further comprises: applying a respective program inhibit voltage to the bit line in each of the program voltage application stage of the first program cycle, the program voltage application stage of the second program cycle, and the program voltage application stage of the third program cycle.

Other voltage application scenarios in FIG. 18 are similar to a voltage application scenario shown in FIG. 12 and are no longer repeated here.

Based on an idea similar to that of the operation method of the memory device described above, the present disclosure provides a memory device, comprising: a memory array and a peripheral circuit coupled with the memory array, wherein the memory array comprises a plurality of memory cell strings and a conductive line coupled with one end of a memory cell string; the peripheral circuit is configured to: apply a first precharge voltage to the conductive line in a precharge stage of a first program cycle; and apply a second precharge voltage to the conductive line in a precharge stage of a second program cycle following the first program cycle, wherein the second precharge voltage is greater than the first precharge voltage.

In some examples, the peripheral circuit is further configured to: apply a third precharge voltage to the conductive line in a precharge stage of a third program cycle following the second program cycle, wherein the third precharge voltage is greater than the second precharge voltage.

In some examples, the first precharge voltage, the second precharge voltage, and the third precharge voltage present a stepwise increasing trend or a linear increasing trend.

In some examples, the peripheral circuit is further configured to: apply a first voltage to a word line coupled with a target memory cell in the precharge stage of the first program cycle; and apply a second voltage to the word line coupled with the target memory cell in the precharge stage of the second program cycle, wherein the second voltage is greater than the first voltage.

In some examples, the memory array further comprises a first word line group adjacent to the word line coupled with the target memory cell; the word line coupled with the target memory cell is located between the conductive line and the first word line group, the first word line group comprises at least one first word line and at least one second word line, the first word line is close to the word line coupled with the target memory cell, and the second word line is away from the word line coupled with the target memory cell; the peripheral circuit is further configured to at least one of: apply a third voltage to the first word line in the precharge stage of the first program cycle, wherein the third voltage is less than or equal to the first voltage; or apply a fourth voltage to the first word line in the precharge stage of the second program cycle, wherein the fourth voltage is less than or equal to the second voltage, and the fourth voltage is greater than the third voltage.

In some examples, the peripheral circuit is further configured to at least one of: apply a fifth voltage to the second word line in the precharge stage of the first program cycle, wherein the fifth voltage is less than the third voltage; or apply a sixth voltage to the second word line in the precharge stage of the second program cycle, wherein the sixth voltage is less than the fourth voltage, and the sixth voltage is greater than the fifth voltage.

In some examples, the first program cycle comprises at least one first pulse stage, and the second program cycle comprises at least one second pulse stage; the peripheral circuit is configured to: apply a corresponding first precharge voltage to the conductive line in each of the first pulse stages; and apply a corresponding second precharge voltage to the conductive line in each of the second pulse stages; in the first program cycle, a first precharge voltage applied in a first pulse stage arranged in the front in sequence is less than or equal to a first precharge voltage applied in a first pulse stage arranged behind in sequence; and in the second program cycle, a second precharge voltage applied in a second pulse stage arranged in the front in sequence is less than or equal to a second precharge voltage applied in a second pulse stage arranged behind in sequence.

In some examples, at least one of: a plurality of first precharge voltages applied correspondingly in the plurality of first pulse stages arranged in sequence present a stepwise increasing trend or a linear increasing trend; or a plurality of second precharge voltages applied correspondingly in the plurality of second pulse stages arranged in sequence present a stepwise increasing trend or a linear increasing trend.

In some examples, the peripheral circuit is configured to: apply a corresponding first voltage to the word line coupled with the target memory cell in each of the first pulse stages; and apply a corresponding second voltage to the word line coupled with the target memory cell in each of the second pulse stages, wherein in the first program cycle, a first voltage applied in a first pulse stage arranged in the front in sequence is less than or equal to a first voltage applied in a first pulse stage arranged behind in sequence; in the second program cycle, a second voltage applied in a second pulse stage arranged in the front in sequence is less than or equal to a second voltage applied in a second pulse stage arranged behind in sequence.

In some examples, at least one of: a plurality of first voltages applied correspondingly in the plurality of first pulse stages arranged in sequence present a stepwise increasing trend or a linear increasing trend; or a plurality of second voltages applied correspondingly in the plurality of second pulse stages arranged in sequence present a stepwise increasing trend or a linear increasing trend.

In some examples, the conductive line comprises a bit line or a common source line.

In some examples, the memory array further comprises a second word line group, the second word line group comprises at least one third word line, and the second word line group is adjacent to the word line coupled with the target memory cell and located between the word line coupled with the target memory cell and the conductive line; the peripheral circuit is further configured to: apply a seventh voltage to the third word line in the precharge stage of the first program cycle; and apply an eighth voltage to the third word line in the precharge stage of the second program cycle, wherein the seventh voltage is less than the eighth voltage.

In some examples, the memory array further comprises a third word line group, the third word line group comprises at least one fourth word line, and the third word line group is located between the second word line group and the conductive line; the peripheral circuit is further configured to: connect the fourth word line to a ground voltage in the precharge stage of the first program cycle and the precharge stage of the second program cycle.

In some examples, the peripheral circuit is further configured to: apply a first program voltage to the word line coupled with the target memory cell in a program voltage application stage of the first program cycle; and apply a second program voltage to the word line coupled with the target memory cell in a program voltage application stage of the second program cycle, wherein the second program voltage is greater than the first program voltage.

In some examples, the conductive line comprises the common source line, and the memory array further comprises a bit line coupled with the other end of the memory cell string; the peripheral circuit is further configured to: apply a program inhibit voltage to bit lines other than a bit line coupled with the target memory cell in the precharge stage and the program voltage application stage of the first program cycle and in the precharge stage and the program voltage application stage of the second program cycle.

Based on an idea similar to that of the operation method of the memory device described above, the present disclosure further provides a memory system, comprising a memory controller and a memory device of any one of above examples, wherein the memory controller is coupled with the memory device and configured to control the memory device.

The present disclosure further provides a computer readable storage medium storing a computer program which, when executed, can implement the operation method of any one of above implementations.

Here, all or part of the processes in the operation method of the above examples may be implemented by instructing relevant hardware through a computer program. The computer program may be stored in a computer-readable storage medium, and the execution of the computer program may comprise the processes of the operation method in any of the above examples. Here, the computer readable storage medium may be a diskette, an optical disk, a Read-Only Memory (ROM), a Random Access Memory (RAM), a Flash Memory, a Hard Disk Drive (HDD), or a solid state drive, etc., and the computer readable storage medium may further comprise a combination of the above various storage media.

The characteristics disclosed in several device examples provided by the present disclosure may be combined freely to obtain new device examples in case of no conflicts.

The methods disclosed in several method examples as provided by the present disclosure may be combined freely to obtain new method examples in case of no conflicts.

The above descriptions are merely example implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory device, comprising:
a memory array comprising a plurality of memory cell strings and a conductive line coupled with one end of a memory cell string; and
a peripheral circuit coupled with the memory array and configured to:
apply a first precharge voltage to the conductive line in a first precharge stage of a first program cycle; and
apply a second precharge voltage to the conductive line in a second precharge stage of a second program cycle after the first program cycle, wherein the second precharge voltage is greater than the first precharge voltage.

2. The memory device of claim 1, wherein the peripheral circuit is further configured to:
apply a third precharge voltage to the conductive line in a third precharge stage of a third program cycle after the second program cycle, wherein the third precharge voltage is greater than the second precharge voltage.

3. The memory device of claim 2, wherein the first precharge voltage, the second precharge voltage, and the third precharge voltage present have values in an increasing order.

4. The memory device of claim 1, wherein the peripheral circuit is further configured to:
apply a first voltage to a word line coupled with a target memory cell in the first precharge stage of the first program cycle; and
apply a second voltage to the word line coupled with the target memory cell in the second precharge stage of the second program cycle, wherein the second voltage is greater than the first voltage.

5. The memory device of claim 4, wherein the memory array further comprises a first word line and a second word line, the first word line is between the second word line and the word line coupled with the target memory cell, and the word line coupled with the target memory cell is between the first word line and the conductive line;
wherein the peripheral circuit is further configured to perform at least one of:
apply a third voltage to the first word line in the first precharge stage of the first program cycle, wherein the third voltage is less than or equal to the first voltage; or
apply a fourth voltage to the first word line in the second precharge stage of the second program cycle, wherein the fourth voltage is less than or equal to the second voltage, and the fourth voltage is greater than the third voltage.

6. The memory device of claim 5, wherein the peripheral circuit is further configured to at least one of:
apply a fifth voltage to the second word line in the first precharge stage of the first program cycle, wherein the fifth voltage is less than the third voltage; or
apply a sixth voltage to the second word line in the second precharge stage of the second program cycle, wherein the sixth voltage is less than the fourth voltage, and the sixth voltage is greater than the fifth voltage.

7. The memory device of claim 4, wherein the first program cycle comprises at least one first pulse stage, and the second program cycle comprises at least one second pulse stage; the peripheral circuit is configured to:
apply a corresponding first precharge voltage to the conductive line in a first precharge stage of each first pulse stage; and
apply a corresponding second precharge voltage to the conductive line in a second precharge stage of each second pulse stage; wherein,
in the first program cycle, the first precharge voltage applied in a first pulse stage arranged in front in sequence is less than or equal to the first precharge voltage applied in a first pulse stage arranged behind in sequence; and
in the second program cycle, a second precharge voltage applied in a second pulse stage arranged in front in sequence is less than or equal to a second precharge voltage applied in a second pulse stage arranged behind in sequence.

8. The memory device of claim 7, wherein the peripheral circuit is configured to:
apply a corresponding first voltage to the word line coupled with the target memory cell in the first precharge stage of each first pulse stage; and
apply a corresponding second voltage to the word line coupled with the target memory cell in the second precharge stage of each second pulse stages, wherein,
in the first program cycle, a first voltage applied in a first pulse stage arranged in front in sequence is less than or equal to a first voltage applied in a first pulse stage arranged behind in sequence; and
in the second program cycle, a second voltage applied in a second pulse stage arranged in front in sequence is less than or equal to a second voltage applied in a second pulse stage arranged behind in sequence.

9. The memory device of claim 1, wherein the conductive line comprises a bit line or a common source line.

10. The memory device of claim 4, wherein the peripheral circuit is further configured to:
apply a first program voltage to the word line coupled with the target memory cell in a program voltage application stage of the first program cycle; and
apply a second program voltage to the word line coupled with the target memory cell in a program voltage application stage of the second program cycle, wherein the second program voltage is greater than the first program voltage.

11. The memory device of claim 10, wherein the conductive line comprises a common source line, and the memory array further comprises a bit line coupled with an other end of the memory cell string; and
the peripheral circuit is further configured to:
apply a program inhibit voltage to bit lines other than a bit line coupled with the target memory cell in the program voltage application stage of the first program cycle and in the program voltage application stage of the second program cycle.

12. A memory system, comprising:
a memory controller; and
a memory device, comprising:
a memory array comprising a plurality of memory cell strings and a conductive line coupled with one end of a memory cell string; and
a peripheral circuit coupled with the memory array and configured to:
apply a first precharge voltage to the conductive line in a first precharge stage of a first program cycle; and
apply a second precharge voltage to the conductive line in a second precharge stage of a second program cycle after the first program cycle, wherein the second precharge voltage is greater than the first precharge voltage,
wherein the memory controller is coupled with the memory device and configured to control the memory device.

13. An operation method of a memory device, wherein the memory device comprises:
a plurality of memory cell strings; and
a conductive line coupled with one end of a memory cell string;
wherein the operation method comprises:
applying a first precharge voltage to the conductive line in a first precharge stage of a first program cycle; and
applying a second precharge voltage to the conductive line in a second precharge stage of a second program cycle after the first program cycle, wherein the second precharge voltage is greater than the first precharge voltage.

14. The operation method of claim 13, further comprising:
applying a third precharge voltage to the conductive line in a third precharge stage of a third program cycle after the second program cycle.

15. The operation method of claim 14, wherein the third precharge voltage is greater than the second precharge voltage; and the first precharge voltage, the second precharge voltage, and the third precharge voltage have values in an increasing order.

16. The operation method of claim 13, further comprising:
applying a first voltage to a word line coupled with a target memory cell in the first precharge stage of the first program cycle; and
applying a second voltage to the word line coupled with the target memory cell in the second precharge stage of the second program cycle, wherein the second voltage is greater than the first voltage.

17. The operation method of claim 16, wherein the memory device further comprises a first word line and a second word line, the first word line is between the second word line and the word line coupled with the target memory cell, and the word line coupled with the target memory cell is between the first word line and the conductive line;
wherein the operation method further comprises at least one of:
applying a third voltage to the first word line in the first precharge stage of the first program cycle, wherein the third voltage is less than or equal to the first voltage; or
applying a fourth voltage to the first word line in the second precharge stage of the second program cycle, wherein the fourth voltage is less than or equal to the second voltage, and the fourth voltage is greater than the third voltage.

18. The operation method of claim 17, further comprising at least one of:
applying a fifth voltage to the second word line in the first precharge stage of the first program cycle, wherein the fifth voltage is less than the third voltage; or
applying a sixth voltage to the second word line in the second precharge stage of the second program cycle, wherein the sixth voltage is less than the fourth voltage, and the sixth voltage is greater than the fifth voltage.

19. The operation method of claim 16, further comprising:
applying a first program voltage to the word line coupled with the target memory cell in a program voltage application stage of the first program cycle; and
applying a second program voltage to the word line coupled with the target memory cell in a program voltage application stage of the second program cycle, wherein the second program voltage is greater than the first program voltage.

20. The operation method of claim 19, wherein the conductive line comprises a common source line, and the memory device further comprises a bit line coupled with an other end of the memory cell string;
wherein the operation method further comprises:
applying a program inhibit voltage to bit lines other than a bit line coupled with the target memory cell in the program voltage application stage of the first program cycle and in the program voltage application stage of the second program cycle.
